(19) United States
(12) Patent Application Publication
(10) Pub. No.: US 2026/0038772 A1
(43) Pub. Date: Feb. 5, 2026

(54) SUBSTRATE PROCESSING APPARATUS

(71) Applicant: Samsung Electronics Co., Ltd., Suwon-si (KR)

(72) Inventors: Wonyoung CHOI, Suwon-si (KR); Minwoo RHEE, Suwon-si (KR); Yongjoo LEE, Suwon-si (KR); Jungshin LEE, Suwon-si (KR)

(21) Appl. No.: 19/016,252

(22) Filed: Jan. 10, 2025

(30) Foreign Application Priority Data
Jul. 30, 2024 (KR) 10-2024-0101008

(51) Int. Cl. H01J 37/32; H01L 23/00

(52) U.S. Cl. CPC H01J 37/32449; H01L 24/80; H01L 2224/80013

(57) ABSTRACT

A substrate processing apparatus that processes a substrate using atmospheric pressure plasma includes a stage configured to support a substrate, a gas supply device configured to supply a mixed gas including an inert gas and a process gas, a reactor configured to receive the mixed gas from the gas supply device and generate plasma at atmospheric pressure, wherein the plasma generated from the reactor is configured to process a surface of the substrate. The gas supply device may include a gas supply unit configured to supply the inert gas, a flow rate controller configured to control a flow rate of a liquid process gas, and a vaporizer configured to vaporize the liquid process gas supplied from the flow rate controller.

### CROSS-REFERENCE TO RELATED APPLICATION

This application claims priority to Korean Patent Application No. 10-2024-0101008, filed on Jul. 30, 2024, in the Korean Intellectual Property Office, the entire contents of which are hereby incorporated by reference.

### FIELD

The present disclosure relates to a substrate processing apparatus.

### BACKGROUND

When manufacturing semiconductor devices or display devices, a substrate surface treatment of the devices may be required. For example, a substrate processing apparatus that performs substrate surface treatment in a substrate bonding process a cleaning process, etc. may be provided. Plasma generated under atmospheric pressure may be used for such substrate surface treatment.

However, in the related substrate processing apparatus, it may be difficult to maintain a certain vaporizing material when performing substrate surface treatment through plasma at atmospheric pressure. Moreover, due to a change in the concentration of the vaporized material, a difference in the level of the surface of the substrate treated through plasma may occur. Accordingly, it may be difficult for the related substrate processing apparatus to perform a substrate surface treatment based on the exact amount of vaporization.

### SUMMARY

In some embodiments, the present disclosure provides a substrate processing apparatus capable of processing a surface of a substrate at atmospheric pressure.

In some embodiments, the present disclosure provides a substrate processing apparatus capable of hydrophilizing the surface of the substrate.

In some embodiments, the present disclosure also provides a substrate processing apparatus capable of improving bonding strength and reliability between substrates.

According to some embodiments, a substrate processing apparatus may include a stage configured to support a substrate, a gas supply device configured to supply a mixed gas including an inert gas and a process gas, wherein the inert gas includes a first inert gas and a second inert gas, and a reactor configured to receive the mixed gas from the gas supply device and generate plasma at atmospheric pressure to thereby process a surface of the substrate with the plasma, wherein the gas supply device may include a gas supply unit configured to supply the inert gas, a flow rate controller configured to control a flow rate of a liquid process gas, and a vaporizer configured to vaporize the liquid process gas supplied from the flow rate controller.

According to some embodiments, a substrate processing apparatus may include a stage configured to support a substrate, a gas supply device configured to supply an inert gas and a process gas, a reactor configured to receive the inert gas and the process gas from the gas supply device and generate plasma, wherein the inert gas includes a first inert gas and a second inert gas, and a processing chamber configured to be at least partially open to maintain atmospheric pressure, the reactor and the stage being in the processing chamber, and the processing chamber being configured to process the surface of the substrate at the atmospheric pressure, in which the gas supply device may include a flow rate controller configured to control a flow rate of a liquid process gas, a vaporizer configured to vaporize a liquid process gas supplied from the flow rate controller and supply the vaporized process gas to the reactor, a first gas supply unit configured to supply the first inert gas to the reactor as a plasma generation gas, and a second gas supply unit configured to supply the second inert gas to the vaporizer as a carrier gas.

According to some embodiments, a substrate processing apparatus may include a stage configured to support a substrate, a gas supply device configured to supply a mixed gas including an argon (Ar) gas and a water vapor (H₂O), a linear reactor configured to receive the mixed gas from the gas supply device and generate linear plasma, wherein a surface of the substrate is processed by plasma generated in the linear reactor and is spaced apart from the linear reactor by a predetermined gap such that the substrate passes through the plasma, and a processing chamber configured to be at least partially open to maintain atmospheric pressure, the linear reactor and the stage being in the processing chamber, and the processing chamber being configured to process the surface of the substrate at the atmospheric pressure, wherein the gas supply device may include a flow rate controller including a storage unit configured to store liquid process gas, and a flow rate regulator connected to the storage unit to control a flow rate of the liquid process gas within the range of 0.01 g/min to 0.08 g/min, a vaporizer configured to vaporize all liquid process gas supplied from the flow rate controller and supply the vaporized process gas to the linear reactor at a constant concentration, a first gas supply unit configured to supply the argon gas to the linear reactor such that the linear reactor generates the plasma, and a second gas supply unit configured to supply the argon gas to the vaporizer as a carrier gas.

According to some embodiments of the present disclosure, the substrate processing apparatus may process the surface of the substrate at atmospheric pressure.

According to some embodiments of the present disclosure, the substrate processing apparatus may hydrophilize the surface of the substrate.

According to some embodiments of the present disclosure, the substrate processing apparatus may improve bonding strength and reliability between substrates.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIGS. 1 and 2 are conceptual diagrams illustrating a main configuration of a substrate processing apparatus according to some embodiments;

FIG. 3 is a conceptual diagram illustrating a main configuration of a gas supply device of FIGS. 1 and 2;

FIG. 4 is a diagram showing a substrate processing process of the substrate processing apparatus from the front;

FIG. 5 is a conceptual diagram illustrating a substrate bonding process according to some embodiments;

FIG. 6 is a graph illustrating a bonding strength of a substrate according to a flow rate of water vapor;

FIG. 7 is a graph illustrating a thickness of a copper oxide film according to the flow rate of water vapor;

FIG. 8 is a diagram illustrating the thickness of a copper oxide film on the substrate;

FIG. 9 is a conceptual diagram illustrating a surface of a plasma-treated substrate;

FIG. 10 is a flowchart illustrating a substrate bonding method according to some embodiments;

FIGS. 11 and 12 are views illustrating a substrate bonding method according to some embodiments;

FIG. 13 is a cross-sectional view illustrating a semiconductor device manufactured with a substrate processing apparatus according to some embodiments;

FIG. 14 is a cross-sectional view illustrating an image sensor manufactured with a substrate processing apparatus according to some embodiments; and

FIG. 15 is a conceptual view illustrating a substrate cleaning process according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, description of some conventional elements or parts are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Likewise, when components are “immediately” adjacent to one another, no intervening components may be present. Further, in the specification, the word “on” or “above” may include on or below the object portion, and does not necessarily mean positioned on the upper side of the object portion based on a gravitational direction.

The terms “first,” “second,” etc., may be used herein merely to distinguish one component, layer, direction, etc. from another. In addition, unless explicitly described to the contrary, the word “comprise” and variations such as “comprises” or “comprising” will be understood to imply the inclusion of stated elements but not the exclusion of any other elements. The term “and/or” includes any and all combinations of one or more of the associated listed items. The term “connected” may be used herein to refer to a physical and/or electrical connection.

Hereinafter, a substrate processing apparatus according to some embodiments of the present disclosure will be described in detail with reference to the drawings.

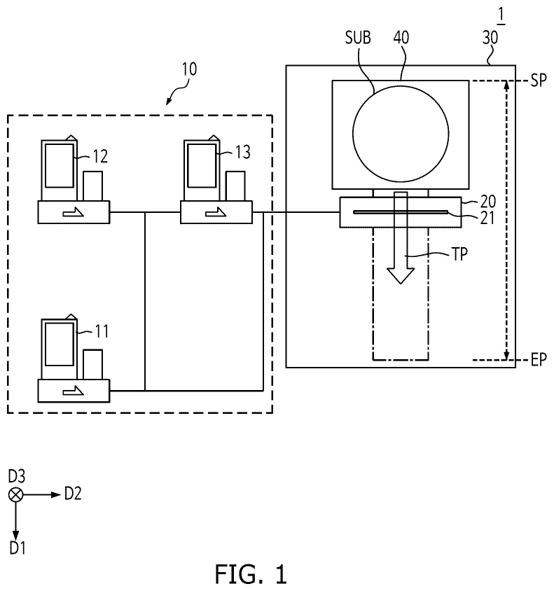

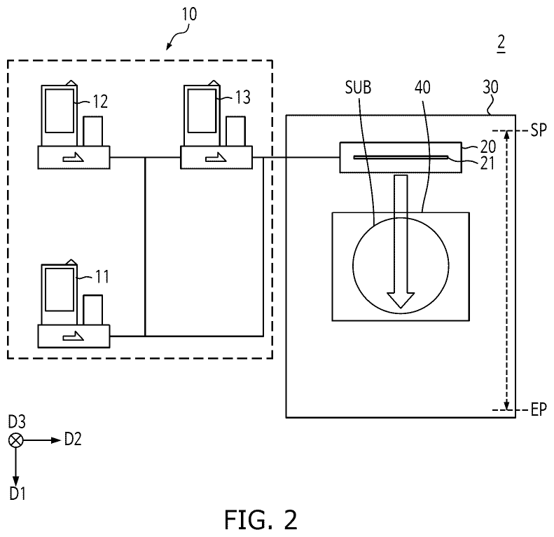

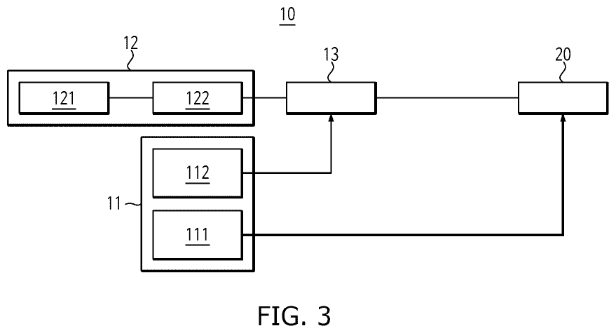

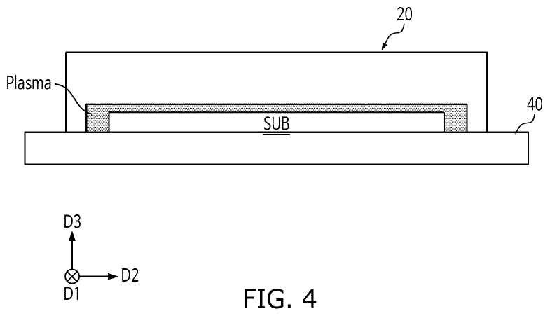

FIGS. 1 and 2 are conceptual diagrams illustrating a main configuration of a substrate processing apparatus according to some embodiments. FIG. 3 is a conceptual diagram illustrating a main configuration of a gas supply device of FIGS. 1 and 2. FIG. 4 is a diagram showing a substrate processing process of the substrate processing apparatus from the front.

Referring to FIGS. 1 to 4, a substrate processing apparatus 1 may include a gas supply device 10, a reactor 20, a processing chamber 30, and a stage 40.

The gas supply device 10 may supply a mixed gas including an inert gas and a process gas. The reactor 20 may receive the mixed gas from a gas supply unit 11 to form plasma. The stage 40 may support a substrate SUB, a surface of which is processed by the plasma generated in the reactor 20. Hereinafter, the substrate SUB may refer to a semiconductor substrate such as a wafer, a chip die, etc. Additionally or alternatively, the substrate SUB may include not only a semiconductor substrate but also a substrate of other technical fields such as a display substrate, a printed circuit board, etc.

The reactor 20 may generate plasma. The reactor 20 may hydrophilize the surface of the substrate SUB supported by the stage 40 by plasma treatment under atmospheric pressure. In this case, the surface of the substrate SUB may refer to a surface that faces the reactor 20 for plasma treatment. The reactor 20 may be provided in a rectangular shape having a long horizontal width. Throughout the description, the atmospheric pressure does not necessarily mean a specific pressure condition, but may refer to a state in a general atmosphere. In addition, the atmospheric pressure as used herein may encompass all pressures that vary according to various weather conditions, such as high pressure, low pressure, etc. Therefore, the condition under atmospheric pressure may mean a state in which the pressure is not adjusted by a separate pressure control means, and is not limited to any specific pressure value defined under a specific condition.

The reactor 20 and the stage 40 may be in the processing chamber 30. At least a portion of the processing chamber 30 may be opened, such that the air pressure in the processing chamber 30 may be maintained at atmospheric pressure. For example, the processing chamber 30 may be provided in a hexahedral shape with one side open, and the reactor 20 and the stage 40 may be accommodated in the processing chamber 30. As another example, the processing chamber 30 may be a plate supporting the reactor 20 and the stage 40. However, the shape of the processing chamber 30 is not limited to these shapes, and the processing chamber 30 may be provided in any form if the reactor 20 and the stage 40 may be placed under atmospheric pressure.

A means for controlling the pressure of the space in which the plasma is formed may be omitted in the processing chamber 30. For example, a vacuum pump, etc. may not be provided in the substrate processing apparatus 1 in some embodiments. That is, the reactor 20 and the stage 40 may be exposed to the atmosphere, such as in an absence of a pressure controller.

At least one of the reactor 20 or the stage 40 may relatively move along a first direction D1. At least one of the reactor 20 or the stage 40 may linearly reciprocate along the first direction D1. For example, the reactor 20 may be fixed, and the stage 40 may move based on the reactor 20. As another example, the stage 40 may be fixed, and the reactor 20 may move. However, embodiments are not limited thereto, and both the reactor 20 and the stage 40 may move.

The reactor 20 may extend in a second direction D2. The second direction D2 may be a direction intersecting the first direction D1. Specifically, the second direction D2 may be a direction perpendicular to the first direction D1. In addition, the first and second directions D1 and D2 may be parallel to an upper surface of the substrate SUB. When the reactor 20 extending in the second direction D2 moves along the first direction D1, a region in which plasma is formed by the reactor 20 may be moved. The region in which the plasma is formed may be approximately a square plane. Alternatively, the reactor 20 may be fixed, and the plasma may scan the surface of the substrate SUB as the substrate SUB supported on the stage 40 moves.

In some embodiments, the reactor 20 may be a reactor including a robotic arm structure. A reactor including a robot arm structure may perform plasma treatment on a target including not only a planar substrate such as a wafer substrate, a display substrate, etc., but also a curved surface, etc. By configuring the reactor to be moveable, a surface treatment on either the substrate and/or any other object may be possible. For example, the surface treatment may refer to hydrophilization.

The stage 40 may move along the first direction D1 at a position spaced apart from the reactor 20 in a third direction D3 such that the substrate SUB passes through the plasma region. For example, the stage 40 may be spaced at a predetermined gap in the downward direction of the reactor 20, and a transfer path TP of the substrate SUB may extend along the first direction D1. The plasma region may be formed in a gap between the reactor 20 and the stage 40. The substrate SUB supported on the stage 40 may be positioned in the gap between the reactor 20 and the stage 40. Accordingly, while the substrate SUB is positioned in the plasma region, a surface treatment on the substrate SUB may be performed.

In the substrate processing apparatus 1 of FIG. 1, the stage 40 supporting the substrate SUB may pass through a lower portion of the reactor 20. The reactor 20 may form a plasma region on at least a portion of the surface of the substrate SUB. The plasma region may be formed to overlap the transfer path TP of the substrate SUB. Under such a configuration, while the substrate SUB passes through the plasma region, the surface of the substrate SUB may be plasma-treated.

In a substrate processing apparatus 2 of FIG. 2, the reactor 20 may move above the substrate SUB supported by the stage 40 in a scan manner. The reactor 20 may be provided with a driving unit configured to move the reactor 20.

Hereinafter, for convenience of description, a plasma treatment process on the surface of the substrate will be described based on the substrate processing apparatus 1 of FIG. 1.

The reactor 20 may include an opening 21 for providing plasma excited by an RF power source (not shown). The reactor 20 may include a linear opening 21 for generating linear plasma. For example, the frequency of the power supplied by the RF power source may be 13.56 MHz to 100 MHz. The opening 21 may extend in a second direction D2 intersecting the first direction D1. For example, the reactor 20 may include the linear opening 21 for providing plasma gas linearly. Under such a configuration, the plasma formed by the reactor 20 may be a linear plasma. The long side length of the opening 21 may be formed to be equal to or greater than the width of the substrate SUB, such that the surface treatment is performed on the width of the surface of the substrate SUB. For example, the length of the opening 21 and the reactor 20 in the second direction D2 may be longer than the length of the substrate SUB in the second direction D2.

An operation state of the reactor 20 may be controlled by a sensor unit and a control unit (not shown). The sensor unit may detect whether the substrate SUB is positioned within a plasma treatment section of the reactor 20. The control unit may stop the operation of the reactor 20 if the substrate SUB is positioned in a section before entering the plasma treatment section or in a section after the plasma treatment section. If the substrate SUB is positioned in the plasma treatment section, the reactor 20 may be operated to generate plasma.

If the stage 40 on which the substrate SUB is seated enters a plasma start position SP in the plasma treatment section, the operation of the reactor 20 may be started by the control unit (not shown), and a plasma region may be formed on the transfer path TP of the substrate SUB. If the stage 40 moves in a straight line along the transfer path TP and passes a plasma end position EP, the operation of the reactor 20 is stopped. Meanwhile, in some cases, the stage 40 may reciprocate along the transfer path TP, and in this case, the operation of the reactor 20 may not be stopped, i.e., the operation of the reactor 20 may be continuous.

The stage 40 may be moved such that the substrate SUB passes through the linear plasma. In order for the surface of the substrate SUB to pass through the plasma region, the transfer height of the substrate SUB and the position of the reactor 20 may be determined such that a vertical gap (e.g., gap in the direction D3) between the substrate SUB and the reactor 20 is smaller than the thickness of the plasma region exposed through the lower portion of the reactor 20. The plasma region may be formed to have a thickness of several millimeters (mm), and in this case, the vertical distance between the substrate SUB and the reactor 20 may be designed to be a distance smaller than the thickness of the plasma region.

It may be set such that arc discharge due to plasma does not occur in the plasma start position SP and the plasma end position EP, and the surface of the substrate SUB may be treated within the plasma treatment section. If the plasma treatment section is set too wide, the operation time of the reactor 20 may be longer than necessary, thereby increasing the process cost. In addition, if the plasma treatment section is set to be excessively narrow, the periphery of the surface of the substrate SUB may be partially surface-treated or unevenly surface-treated.

In some embodiments, the plasma start position SP and the plasma end position EP may be set to be a position at which a front end of the substrate SUB starts to enter the plasma region and a position at which a rear end of the substrate SUB starts to exit the plasma region, respectively. The transfer speed of the substrate SUB in the plasma treatment section may be set to be equal to or slower than the transfer speed of the stage 40 before and after the plasma treatment section.

If the surface of the substrate SUB may be sufficiently treated without slowing the transfer speed of the stage 40 in the plasma treatment section, the substrate SUB may be transferred at a constant speed without a speed change in the plasma treatment section to improve productivity. For example, the moving speed of the reactor 20 or the stage 40 may be about 5 mm/s to about 60 mm/s, but is not limited thereto. For example, for the surface treatment of a 300 mm wafer substrate, the reactor 20 or the stage 40 may move at 10 mm/s for 30 seconds. The transfer speed of the stage 40 may be slowed in the plasma treatment section to increase a deposition time, and the stage 40 may be reciprocated a plurality of times so that the substrate SUB may be positioned several times in the plasma treatment section.

Referring to FIG. 3, the gas supply device 10 may include a gas supply unit 11, a flow rate controller 12, and a vaporizer 13. The gas supply unit 11 may supply an inert gas.

The gas supply unit 11 may supply an inert gas. The inert gas may include argon Ar, but is not limited thereto. For example, the inert gas may include nitrogen N2, helium He, etc.

The gas supply unit 11 may include a first gas supply unit 111 that supplies a first inert gas to the reactor 20 as a plasma generation gas, and a second gas supply unit 112 that supplies a second inert gas to the vaporizer 13 as a carrier gas. The first inert gas supplied from the first gas supply unit 111 and the second inert gas supplied from the second gas supply unit 112 may be the same as or different from each other. In addition, as shown in FIG. 3, the thickness of the line connected to the gas supply unit 11 may represent a flow rate of the gas to be supplied. That is, the flow rate of the gas supplied from the first gas supply unit 111 may be greater than the flow rate of the gas supplied from the second gas supply unit 112.

The reactor 20 may receive the first inert gas as a plasma generation gas from the first gas supply unit 111 to generate plasma. For example, the first gas supply unit 111 may supply argon of about 15 Lpm to 20 Lpm to the reactor 20 to generate plasma. This is only an example, and any suitable amount to generate plasma may be used. In addition, the amount of the first inert gas supplied by the first gas supply unit 111 is not limited to the above example, and may vary depending on the type or composition ratio of the first inert gas. The second inert gas supplied by the second gas supply unit 112 may be the carrier gas and may be supplied to the vaporizer 13 at a constant concentration. The second gas supply unit 112 may supply a constant flow rate of carrier gas to the vaporizer 13. The flow rate of the carrier gas supplied by the second gas supply unit 112 may be constant. For example, the second gas supply unit 112 may supply approximately 1 Lpm of argon. In some embodiments, the gas supply unit 11 may be configured integrally, and the supply flow path may be formed separately.

The flow rate controller 12 may supply the process gas to the reactor 20. The flow rate controller 12 may include a storage unit 121 for storing a liquid process gas, and a flow regulator 122 connected to the storage unit 121. For example, the storage unit 121 may be a canister. The flow regulator 122 may control the flow rate of the liquid process gas. For example, the storage unit 121 may store deionized water, and the flow regulator 122 may control the flow rate of the deionized water supplied from the storage unit 121. The liquid process gas may mean that the process gas is in a liquefied state or state before vaporization. That is, it may refer to a case in which the same material as the process gas is in a liquid state. For example, the process gas may be water vapor, and the liquid process gas may be water, deionized water, distilled water, etc. In this case, the substrate surface treatment using the deionized water may refer to hydrophilization. As another example, the process gas may be gaseous carbon dioxide, and the liquid process gas may be liquid carbon dioxide.

The flow rate controller 12 may supply the liquid process gas to the vaporizer 13. The flow rate controller 12 may control the flow rate of the liquid process gas. The flow rate controller 12 may be provided with a flow rate sensor that measures the flow rate of the liquid process gas and a control unit that controls the flow rate of the process gas. For example, the flow rate controller 12 may include a liquid mass flow rate meter (LMFM). However, embodiments are not limited thereto, and various types of flow rate meters or flow regulators may be used.

The flow rate controller 12 may control the flow rate of the liquid process gas at atmospheric pressure. The flow rate controller 12 may control a low flow rate. For example, the flow rate controller 12 may control the flow rate of the liquid process gas in a unit of 0.01 g/min. The flow rate controller 12 may control the flow rate of the liquid process gas within the range of 0.01 g/min to 0.10 g/min. However, embodiments are not limited to the above, and the flow rate controller 12 may control the flow rate of the liquid process gas in smaller or larger units.

The vaporizer 13 may vaporize the liquid process gas supplied from the flow rate controller 12. For example, the vaporizer 13 may be a boiler. On the other hand, the liquid process gas may be vaporized by a bubbler instead of the vaporizer 13. The vaporizer 13 may supply the vaporized process gas, that is, the gaseous process gas, to the reactor 20 through the carrier gas. In some embodiments, the vaporizer 13 may vaporize all or substantially all liquid process gas supplied from the flow rate controller 12. In some embodiments, the vaporizer 13 may vaporize 100% of the liquid process gas supplied from the flow rate controller 12. The vaporizer 13 may vaporize all liquid process gas supplied from the flow rate controller 12 and supply the vaporized process gas to the reactor 20 at a constant concentration.

The process gas may include various gases that can hydrophilize the surface of the substrate SUB by plasma. For example, the process gas may include water vapor H₂O. However, the type of the process gas is not limited thereto, and may include various gases that can generate a hydroxyl group (—OH) while vaporizing. In some embodiments, the process gas may include NH₄OH, etc.

The amount of the process gas vaporized in the vaporizer 13 may be calculated from the flow rate of the liquid measured in the flow rate controller 12. Therefore, because the vaporizer 13 vaporizes all liquid process gas supplied from the flow rate controller 12, the amount of process gas may be calculated from the liquid flow rate.

On the other hand, if the liquid process gas (e.g., water) flows into the reactor 20, arcing may occur in the reactor. In the substrate processing apparatuses 1 and 2 according to some embodiments of the present disclosure, because all process gas is vaporized in the vaporizer 13, it is possible to reduce or prevent liquid process gas from flowing into the reactor 20. That is, the reactor 20 may generate plasma in a state where arcing is less likely to occur or is removed.

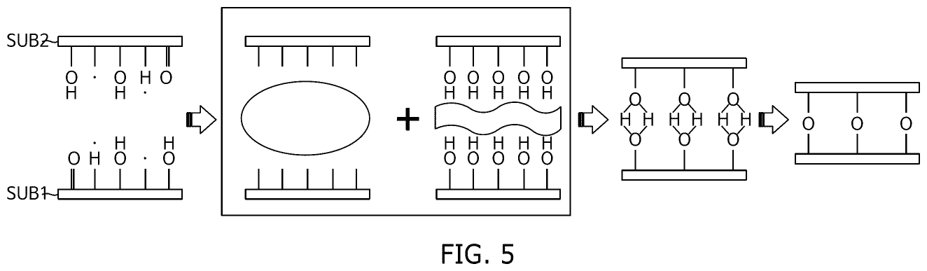

The path through which the vaporizer 13 supplies gas to the reactor 20 and the path through which the gas supply unit 11 supplies gas to the reactor 20 are shown to be separated from each other, but are not limited thereto. A confluence portion and a flow regulator may be present in the path through which the gas is introduced into the reactor 20. The flow regulator may control the pressure of the mixed gas provided to the reactor 20. The inert gas and the process gas (e.g., water vapor) may be mixed and present in the mixed gas. The surface activation treatment of the substrate SUB may be possible by atmospheric pressure plasma formed according to the flow rate of the mixed gas. The surface treatment of the substrate SUB may be used to bond a plurality of substrates, which will be described in detail with reference to FIGS. 5 to 14.

FIGS. 1 to 4 illustrate the reactor 20 receiving the mixed gas and generating plasma at atmospheric pressure, but embodiments are not limited thereto, and any device (e.g., head, etc.) capable of generating plasma at atmospheric pressure may be used.

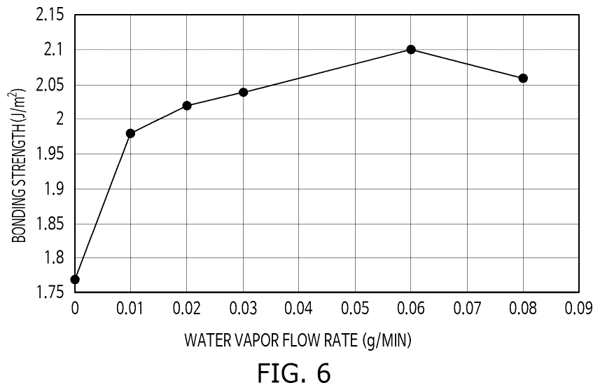

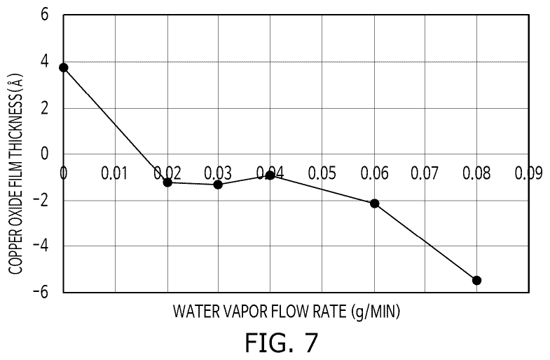

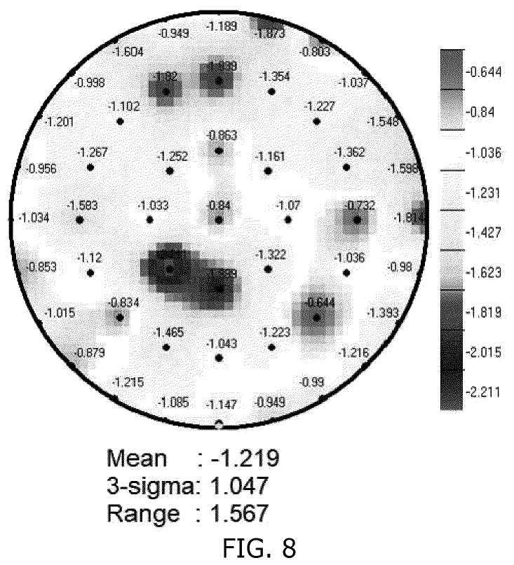

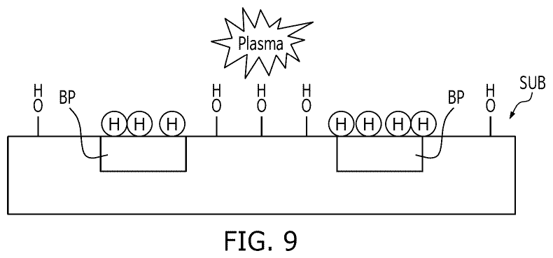

FIG. 5 is a conceptual diagram illustrating a substrate bonding process according to some embodiments. FIG. 6 is a graph illustrating a bonding strength of a substrate according to the flow rate of water vapor. FIG. 7 is a graph illustrating the thickness of a copper oxide film according to the flow rate of water vapor. FIG. 8 is a diagram illustrating the thickness of a copper oxide film on the substrate. FIG. 9 is a conceptual diagram illustrating the surface of substrate after surface treatment.

Referring to FIGS. 5 and 6, a first substrate SUB1 and a second substrate SUB2 may be surface-treated, respectively, using the substrate processing apparatus in accordance with some embodiments. That is, the substrate bonding method using the substrate processing apparatus according to some embodiments will be described.

In the substrate-to-substrate bonding process, plasma surface treatment may be performed on each substrate to bond the first substrate SUB1 and the second substrate SUB2, which are manufactured using various insulating materials such as silicon oxide, silicon nitride, silicon carbonitride, and conductive materials such as copper (Cu), without using an adhesive or in an absence of an adhesive.

First, plasma may be formed at atmospheric pressure using the mixed gas of the inert gas and water vapor on a bonding surface of the first substrate SUB1, and the surface (i.e., the bonding surface) of the first substrate SUB1 may be activated. In substantially the same method as described above, plasma may be formed at atmospheric pressure using the mixed gas on a bonding surface of the second substrate SUB2, and the bonding surface of the second substrate SUB2 may be activated.

Through plasma surface treatment, a dangling bond is formed on the surface of the substrate, and the surface of the substrate has high surface energy. For example, the hydroxyl group (—OH) may attach to the dangling bond formed on the surface of the substrate through hydrophilization. An initial bond between the first substrate SUB1 and the second substrate SUB2 may be formed by a hydrogen bond of the hydroxyl group (—OH). In this way, hydrophilization using plasma may be performed on each of the bonding surfaces of the first substrate SUB1 and the second substrate SUB2, and the bonding surface of the first substrate SUB1 and the bonding surface of the second substrate SUB2 may be bonded. The first substrate SUB1 and the second substrate SUB2 may be bonded through a high-temperature annealing process.

Each of the first substrate SUB1 and the second substrate SUB2 may move at a constant speed through the lower portion of the reactor 20 in which plasma is generated. Each of the first substrate SUB1 and the second substrate SUB2 may be seated on the stage 40 that is performing a linear reciprocating motion. In addition, each of the first substrate SUB1 and the second substrate SUB2 may repeatedly move the upper portion of the reactor 20 a plurality of times so that hydrophilization of the bonding surfaces may be performed. Due to the hydrophilization, a hydroxyl group (—OH) may be distributed on each of the bonding surface of the first substrate SUB1 and the bonding surface of the second substrate SUB2.

The specific process conditions of the atmospheric pressure plasma are as follows.

TABLE 1

| | Source | | Flow | | | | Bonding |
|---|---|---|---|---|---|---|---|
| | Power | Ar | rate | Pressure | Time | Annealing | Strength |
| | (W) | (Lpm) | (g/min) | (Torr) | (min) | (° C./hr) | (J/m²) |
| Comparative | 400 | 20 | 0 | 760 | 30 | 350 | 1.77 |
| Example | | | | | | | |
| Experimental | 400 | 16 | 0.01 | 760 | 30 | 350 | 1.98 |
| Example 1 | | | | | | | |
| Experimental | 400 | 16 | 0.02 | 760 | 30 | 350 | 2.02 |
| Example 2 | | | | | | | |
| Experimental | 400 | 16 | 0.03 | 760 | 30 | 350 | 2.04 |
| Example 3 | | | | | | | |
| Experimental | 400 | 16 | 0.06 | 760 | 30 | 350 | 2.10 |
| Example 4 | | | | | | | |
| Experimental | 400 | 16 | 0.08 | 760 | 30 | 350 | 2.06 |
| Example 5 | | | | | | | |

Referring to Table 1 and FIG. 6, the flow rate of the process gas may be adjusted in a unit of about 0.01 g/min in Experimental Examples 1 to 5. The flow rate of the process gas may be adjusted within the range of 0.01 g/min to 0.10 g/min. Specifically, the flow rate of the process gas may be adjusted to any one of 0.01 g/min to 0.08 g/min. In addition, in the graph of FIG. 6, the X-axis may represent the flow rate (g/min) of water vapor, and the Y-axis may represent the bonding strength (J/m²).

In addition, the source power (or RF power) for forming plasma at atmospheric pressure may be adjusted in the range of about 200 W to 500 W. By generating plasma with relatively low power, a chance of damage or failure of the reactor 20 may be reduced or prevented. For example, when the RF frequency is 13.56 M, the source power may be adjusted to about 400 W. Although not shown in Table 1, the RF frequency may be adjusted in a range of about 13.56 M to about 100 M.

Under such conditions, the bonding strength of the first substrate SUB1 and the second substrate SUB2 may be about 1.98 J/m² or more. The bonding strength between the substrates may be calculated as an average value of values measured at four points spaced 90 degrees apart on the surface of the wafer substrate. For example, with one point on the substrate at 0 degree, the bonding strengths may be measured from at 90 degrees, 180 degrees, and 270 degrees, respectively, and the average of the bonding strengths at each point may be calculated. This is an example, and the method for measuring bonding strength is not limited thereto.

In a comparative example, without a supply of the process gas, the bonding strength of the first substrate SUB1 and the second substrate SUB2 may be about 1.77 J/m². In the Experimental Examples 1 to 5, the bonding strength between the first substrate SUB1 and the second substrate SUB2 may be improved by the supply of the process gas. In the comparative example, since the carrier gas and the water vapor are not supplied, supplying more argon (Ar) gas may be desirable for the plasma generation.

Referring to FIGS. 7 to 9, a copper oxide (CuOₓ) film may be formed between the copper (Cu)-copper (Cu) between the substrates on which the annealing process is completed. In this example, x may be any natural number that the copper oxide film may be formed by the copper and oxygen bonding. If the thickness of the copper oxide (CuOₓ) film is thick, electrical properties may be deteriorated in the subsequent process. That is, if the copper oxide (CuOₓ) film is thick, conductive characteristics of copper (Cu)-copper (Cu) may be impaired. For example, a copper oxide (CuOₓ) film may deteriorate the electrical properties of semiconductor chips, increase power consumption and heat generation, and slow signal transmission, thereby lowering the performance of the semiconductor chips. Reducing the thickness of the copper oxide (CuOₓ) film while maintaining the bonding strength at about 2 J/m² may improve performance of the semiconductor chips.

In order to reduce or prevent the performance degradation of the semiconductor chips due to the thickness of the copper oxide (CuOₓ) film, use of hydrogen (H₂) that is a reducing gas to remove oxygen (O₂) during plasma surface treatment is being considered, but the use of hydrogen (H₂) may be difficult to apply in practice due to issues with facility safety standards. In order to solve this problem, the technical idea of the present disclosure is to supply a mixture of the gas to generate plasma and the water vapor that is a vaporizing material, to thus improve the process conditions where the vaporized mixed gas is constantly supplied and maintained into the reactor.

Referring to FIG. 9, solubility may vary depending on the inert gas used as the carrier gas, but the process gas (e.g., water vapor (H₂O)) may be decomposed into a hydroxyl group (—OH) and a hydrogen atom (H) in atmospheric pressure plasma. Alternatively, in atmospheric pressure plasma, the process gas (e.g., water vapor (H₂O)) may be decomposed into oxygen atoms (O) and hydrogen molecules (H₂). Due to the interaction between plasma and water vapor, the hydroxyl group (—OH) may contribute to increasing bonding strength. If a relatively large amount of water vapor is included, more hydroxyl group (—OH) may be generated to contribute to the bonding strength of the substrate SUB.

A bonding pad BP may be formed on the substrate SUB. The bonding pad BP may include a conductive material. For example, the bonding pad BP may include copper (Cu). Meanwhile, the hydrogen atoms (H) or hydrogen molecules (H₂) may reduce or prevent binding of oxygen atoms (O) or oxygen molecules (O₂) to the bonding pad BP of the substrate SUB. That is, the hydrogen atom (H) or the hydrogen molecule (H₂) may reduce or prevent oxidation of the bonding pad BP. With respect to the thickness of the copper oxide (CuOₓ) film, hydrogen atoms (H) or hydrogen molecules (H₂) generated during the decomposition of water (H₂O) may interfere with the bonding of copper (Cu) to the oxygen atoms (O) or oxygen molecules (O₂) on the surface of copper (Cu), thereby reducing the thickness of the copper oxide (CuOₓ) film.

TABLE 2

| | | | | | Copper oxide |
|---|---|---|---|---|---|
| | Power | Pressure | Ar | Vapor | film thickness |
| | (W) | (Torr) | (Lpm) | (g/min) | (Å) |
| Comparative | 400 | 760 | 16 | 0 | 3.774 |
| Example | | | | | |
| Experimental | 400 | 760 | 16 | 0.02 | −1.219 |
| Example 1 | | | | | |
| Experimental | 400 | 760 | 16 | 0.03 | −1.307 |
| Example 2 | | | | | |
| Experimental | 400 | 760 | 16 | 0.04 | −0.912 |
| Example 3 | | | | | |
| Experimental | 400 | 760 | 16 | 0.05 | −0.672 |
| Example 4 | | | | | |
| Experimental | 400 | 760 | 16 | 0.08 | −5.494 |
| Example 5 | | | | | |

Referring to Table 2 and FIG. 7, the flow rate of the process gas may be adjusted in a unit of about 0.01 g/min in the Experimental Examples 1 to 5. The flow rate of the process gas may be adjusted within the range of 0.01 g/min to 0.10 g/min. For example, the flow rate of the process gas may be adjusted to 0.02 g/min to 0.08 g/min.

It was confirmed that, as a result of measuring the thickness of the copper oxide (CuOₓ) film, a copper oxide (CuOₓ) film with a thickness lower than that of the copper oxide film in the comparative example was formed. Specifically, in the graph of FIG. 7, the X-axis may represent a flow rate (g/min) of the water vapor, and the Y-axis may represent a thickness (Å) of the copper oxide (CuOₓ) film. As shown in Table 2, in the Comparative Example, a copper oxide (CuOₓ) film may be formed to have a thickness of about 3.774 Å on average. On the other hand, in the Experimental Examples 1 to 5, it was confirmed that the thickness of the copper oxide (CuOₓ) film was formed to a thickness of about −0.600 Å or less. FIG. 8 illustrates a distribution of the thickness of the copper oxide film of Experimental Example 1 in which the flow rate of the process gas is 0.02 g/min. Although it varies depending on locations, the drawing illustrates a thickness of −0.600 Å or less as a whole, and a thickness of −1.219 Å on average. As described above, the water vapor (H₂O) contained in the mixed gas may ensure the bonding strength between the substrates, thus reducing or preventing the formation of a copper oxide film.

A substrate bonding method according to some embodiments may form a copper oxide (CuOₓ) film with a thickness of about −0.600 Å or less by performing hybrid bonding using atmospheric pressure plasma and water vapor to form a substrate-to-substrate bonding structure. Under this method, the bonding strength and electrical properties between the bonding pads may be improved. The substrate bonding method in some embodiments has been described by referring to hybrid bonding as an example, but embodiments are not limited thereto.

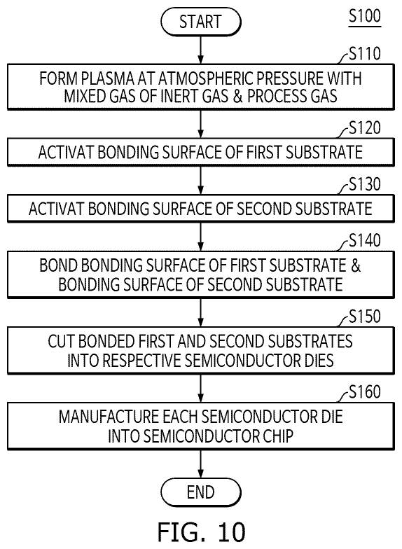

FIG. 10 is a flowchart illustrating a substrate bonding method according to some embodiments.

Referring to FIG. 10, a substrate bonding method S100 according to some embodiments may include a sequence of first to sixth processes S110 to S160.

If any aspect may be implemented differently, a specific order of processes may be different from the order described herein. For example, two processes described in succession may be performed substantially simultaneously, or may be performed in reverse order.

The substrate bonding method S100 according to some embodiments may form plasma at atmospheric pressure by using a mixed gas of an inert gas and a process gas, at S110. The method may include a second process S120 of surface-activating the bonding surface of the first substrate using atmospheric pressure plasma, a third process S130 of forming plasma at atmospheric pressure using the same mixed gas and surface-activating the bonding surface of the second substrate, a fourth process S140 of bonding the bonding surface of the first substrate to the bonding surface of the second substrate, a fifth process S150 of cutting the bonded first and second substrates into respective semiconductor dies, and a sixth process S160 of manufacturing each semiconductor die into a semiconductor chip.

Hereinafter, various structures manufactured by applying the substrate bonding method according to some embodiments will be described.

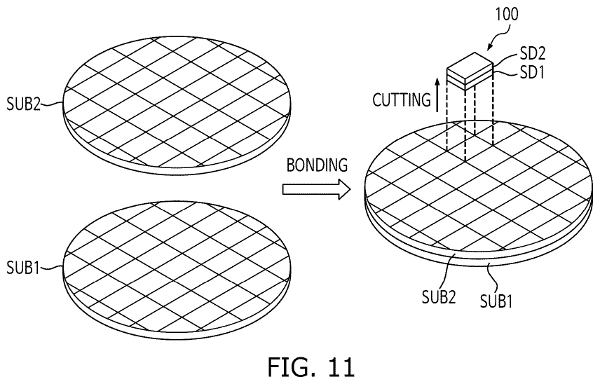

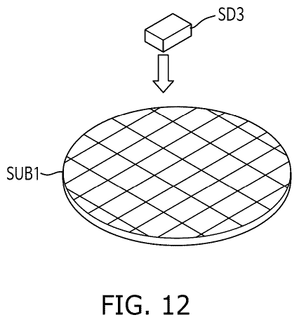

FIGS. 11 and 12 are views provided to explain a substrate bonding method according to some embodiments.

Referring to FIG. 11, a first structure may be formed on the first substrate SUB1, and a second structure may be formed on the second substrate SUB2. The first substrate SUB1 and the second substrate SUB2 are bonded, and with the first substrate SUB1 and the second substrate SUB2 being bonded, the first substrate SUB1 and the second substrate SUB2 may be cut to form a plurality of chips 100.

Each of the plurality of chips 100 may include a first semiconductor die SD1 and a second semiconductor die SD2 stacked to overlap each other. The plurality of chips 100 may include at least one of a semiconductor device 200 and an image sensor 400 to be described below. The first semiconductor die SD1 may be obtained from the first substrate SUB1, and the second semiconductor die SD2 may be obtained from the second substrate SUB2. On the contrary, the first semiconductor die SD1 may be obtained from the second substrate SUB2, and the second semiconductor die SD2 may be obtained from the first substrate SUB1.

Referring to FIG. 12, the first structure may be formed on the first substrate SUB1, and the second structure may be formed on the second substrate (not shown). Before the second substrate is bonded to the first substrate SUB1, the second substrate may be cut to form a third semiconductor die SD3. The third semiconductor die SD3 may be pressed in an arrowed direction to be bonded to a partial area on the first substrate SUB1.

As such, the substrate processing apparatus according to some embodiments may be used for the surface treatment of a substrate or die during a die-to-substrate bonding process. That is, the technical idea of the present disclosure is not limited to a substrate-to-substrate bonding process. As described above, throughout the description, the substrate may be understood as a concept encompassing all of a wafer, a chip, and a die.

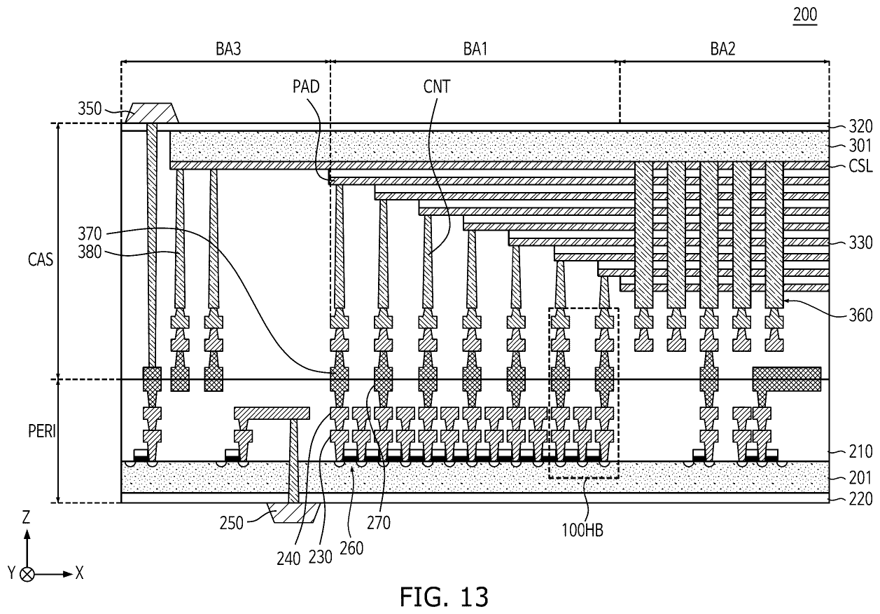

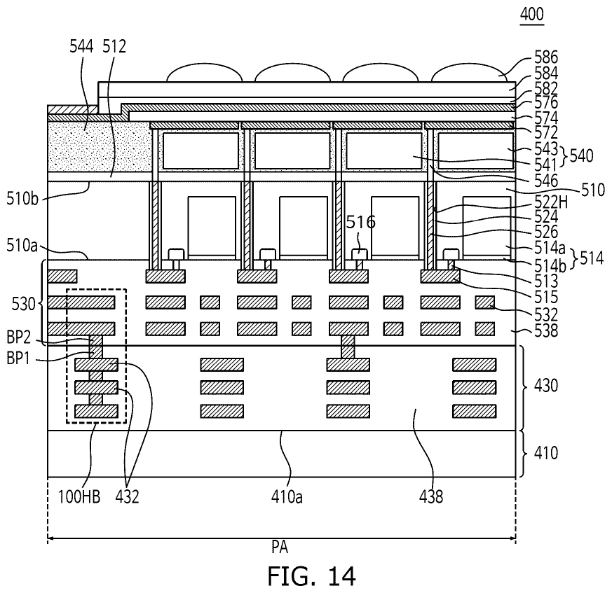

FIG. 13 is a cross-sectional view illustrating a semiconductor device manufactured by a substrate processing apparatus according to some embodiments. FIG. 14 is a cross-sectional view illustrating an image sensor manufactured by a substrate processing apparatus according to some embodiments.

Referring to FIG. 13, the semiconductor device 200 according to some embodiments may include a chip-to-chip structure in which an upper substrate including a cell array structure CAS is fabricated, a lower substrate including a peripheral circuit structure PERI is fabricated, and the upper substrate and the lower substrate are connected to each other by a bonding method.

In some embodiments, the bonding method may refer to how a bonding pad formed at the top end of the upper chip and a bonding pad formed at the top end of the lower chip contact each other. The bonding method may include a metal-metal bonding structure, a through silicon via (TSV), a back via stack (BVS), an eutectic bonding structure, a ball grid array bonding structure, a plurality of wiring lines, or any combination of these.

The bonding method according to some embodiments may include a hybrid bonding 100HB. Since the method of implementing the hybrid bonding 100HB is substantially the same as that already described above, a detailed description thereof will be omitted.

The peripheral circuit structure PERI may include a circuit board 201, an interlayer insulating layer 210, a plurality of circuit elements 260, a first metal layer 230 connected to each of the plurality of circuit elements 260, and a second metal layer 240 formed on the first metal layer 230.

The interlayer insulating layer 210 may be on the circuit board 201 to cover the plurality of circuit elements 260, the first metal layer 230, and the second metal layer 240 and may include an insulating material.

A lower bonding pad 270 may be formed on the second metal layer 240 of a word line bonding area BA1. In the word line bonding area BA1, the lower bonding pad 270 of the peripheral circuit structure PERI may be electrically connected to the upper bonding pad 370 of the cell array structure CAS by the bonding method.

The cell array structure CAS may provide at least one memory block. The cell array structure CAS may include a cell substrate 301 and a common source line CSL. Word lines 330 may be stacked on the cell substrate 301 in the third direction (Z direction).

In a bit line bonding area BA2, a channel structure 360 may be formed through the word lines 330, string select lines, and ground select line in the third direction (Z direction).

In the word line bonding area BA1, the word lines 330 may extend parallel to an upper surface of the cell substrate 301 and may be connected to a plurality of contact plugs CNT. The word lines 330 and the plurality of contact plugs CNT may be connected to each other on a pad portion PAD provided by extending the word lines 330 to different lengths.

A common source line contact 380 may be in an external pad bonding area BA3. The common source line contact 380 may be formed of a conductive material such as a metal, a metal compound, or polysilicon, and may be electrically connected to the common source line CSL.

Meanwhile, input/output pads 250 and 350 may be in the external pad bonding area BA3. A lower film 220 covering a lower surface of the circuit board 201 may be formed under the circuit board 201, and a first input/output pad 250 may be formed on the lower film 220. An upper film 320 covering the upper surface of the cell substrate 301 may be formed on an upper portion of the cell substrate 301, and a second input/output pad 350 may be on the upper film 320.

The semiconductor device 200 manufactured by the substrate bonding method according to some embodiments performs hybrid bonding 100HB using atmospheric pressure plasma, thereby improving bonding strength and electrical properties between the bonding pads.

Referring to FIG. 14, the image sensor 400 may include a pixel area PA including a plurality of unit pixels. The image sensor 400 may include first and second substrates 410 and 510, a first structure 430 formed on a first surface 410a of the first substrate 410, and a second structure 530 formed on a first surface 510a of the second substrate 510. The first structure 430 and the second structure 530 may be bonded to the first surface 410a of the first substrate 410 and the first surface 510a of the second substrate 510 to face each other. In some embodiments, the bonding method may refer to how the first bonding pad BP1 of the first structure 430 and the second bonding pad BP2 of the second structure 530 are in contact with each other.

The bonding method may include a hybrid bonding 100HB. Since the method of implementing the hybrid bonding 100HB is substantially the same as that already described above, a detailed description thereof will be omitted.

The first structure 430 may be formed on the first surface 410a of the first substrate 410. The first structure 430 may include first wiring layers 432 formed at various levels of the pixel area PA, contact plugs connecting the first wiring layers 432 to each other, and a first interlayer insulating film 438 covering these.

In some embodiments, the pixel area PA of the first substrate 410 may correspond to a device region. That is, a logic device for controlling the image sensor 400 may be in the device region of the first substrate 410. A second structure 530 may be formed on the first surface 510a of the second substrate 510. The second structure 530 may include second wiring layers 532 formed at different levels of the pixel area PA, contact plugs connecting the second wiring layers 532 to each other, and a second interlayer insulating film 538 covering these.

A plurality of photoelectric conversion devices 514 may be in the pixel area PA of the second substrate 510. The photoelectric conversion device 514 may be in each unit pixel of the pixel area PA. In some embodiments, the photoelectric conversion device 514 may be a photodiode.

The photoelectric conversion device 514 may include a first impurity region 514a and a second impurity region 514b. A storage node region 516 may be adjacent to the photoelectric conversion device 514.

A contact via 513 that contacts the storage node region 516 and extends into the second structure 530, and a buffer layer 515 that contacts the contact via 513 may be formed in the second structure 530. The buffer layer 515 may be electrically connected to the storage node region 516 through the contact via 513.

A via hole 522H that extends through the second substrate 510 from the second surface 510b to the buffer layer 515 may be formed in the pixel area PA of the second substrate 510. A via insulating film 524 may be formed on a sidewall of the via hole 522H. The via insulating film 524 may be formed of silicon oxide or silicon nitride. The via hole 522H may be filled with a via plug 526. The via plug 526 may fill the via hole 522H to be in contact with the via insulating film 524.

The second surface 510b of the second substrate 510 may be partially recessed to form an anti-reflection layer 512 that covers the second surface 510b flatly. The anti-reflection layer 512 may reduce or prevent reflection of incident light from the outside that strikes the second substrate 510, and thus may allow more incident light to the photoelectric conversion device 514.

On the second surface 510b of the second substrate 510, a color filter layer 540 may be formed on an upper portion of the anti-reflection layer 512. The color filter layer 540 may pass incident light through microlenses 586 such that light having a specific wavelength or wavelength range may enter the photoelectric conversion device 514.

In some embodiments, the color filter layer 540 may include a first color filter layer 541 and a second color filter layer 543. The first color filter layer 541 or second color filter layer 543 corresponding to the photoelectric conversion device 514 may be in each unit pixel of the pixel area PA. A cover insulating layer 544 covering the color filter layer 540 may be formed on the second surface 510b of the second substrate 510. In some embodiments, the cover insulating layer 544 may have a multilayer structure. A portion of the cover insulating layer 544 may be between the color filter layer 540 and the anti-reflection layer 512, and another portion of the cover insulating layer 544 may be on an upper surface of the color filter layer 540.

In the cover insulating layer 544, a second via plug 546 may be formed through the cover insulating layer 544 and is electrically connected to the via plug 526. The second via plug 546 may integrally formed by extending from an upper surface to a lower surface of the cover insulating layer 544.

A lower transparent electrode layer 572 may be formed on the cover insulating layer 544. There may be a plurality of lower transparent electrode layers 572 spaced apart from each other to correspond to each of the plurality of photoelectric conversion devices 514.

A photoelectric layer 574 may be formed on the lower transparent electrode layer 572, and an upper transparent electrode layer 576 may be formed on the photoelectric layer 574. The upper transparent electrode layer 576 may be integrally formed over the pixel area PA. That is, the upper transparent electrode layer 576 may be integrally formed over the plurality of photoelectric conversion devices 514.

The second cover insulating layer 582 may be formed on the cover insulating layer 544 and the upper transparent electrode layer 576. The second cover insulating layer 582 may be formed of a transparent insulating material. The second cover insulating layer 582 may be formed of, for example, silicon oxide.

In some embodiments, a third cover insulating layer 584 may be formed on the second cover insulating layer 582. The third cover insulating layer 584 may be formed to cover an upper surface of the second cover insulating layer 582.

In the pixel area PA of the second substrate 510, the microlens 586 corresponding to the color filter layer 540 may be formed on the third cover insulating layer 584. In some embodiments, if the third cover insulating layer 584 is omitted, the microlens 586 may be formed on the second cover insulating layer 582. The microlens 586 may be formed to overlap the corresponding color filter layer 540.

The image sensor 400 manufactured with the substrate bonding method according to some embodiments may have excellent bonding strength and bonding reliability between the bonding pads by the hybrid bonding 100HB performed using atmospheric pressure plasma.

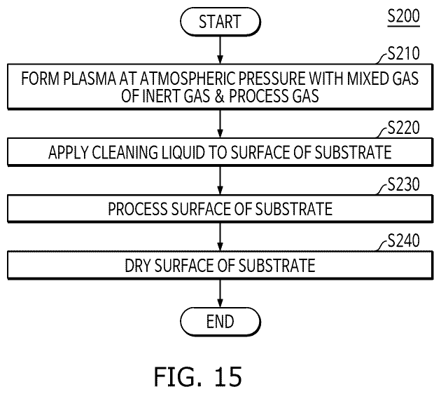

FIG. 15 is a conceptual view illustrating a substrate cleaning process according to some embodiments.

Referring to FIG. 15, a substrate processing apparatus according to some embodiments may be used in the substrate cleaning process. A substrate cleaning method S200 according to some embodiments may include first to fourth processes S110 to S140.

If any aspect may be implemented differently, a specific order of processes may be performed differently from the order described herein. For example, two processes described in succession may be performed substantially simultaneously, or may be performed in the reverse order. In addition, after some processes of the substrate cleaning method are repeated, another process may proceed.

The substrate cleaning method S200 according to some embodiments may include forming plasma at atmospheric pressure using a mixed gas of inert gas and process gas, at S210. For example, by forming hydrophilization, that is, by forming a hydroxyl group (—OH) on the surface of the substrate, particles remaining on the surface may be efficiently removed. In addition, it is possible to reduce or prevent particles from re-attaching to the surface of the substrate.

The substrate cleaning method S200 according to some embodiments may include applying a cleaning liquid to a surface of the substrate to be cleaned, at S220. The cleaning liquid may be applied to the substrate in the form of fine particles by a nozzle, etc. The cleaning liquid applied to the substrate may include a hydrophilic material such as water (H₂O). The method may include performing surface-activating treatment of the substrate using atmospheric pressure plasma after or simultaneously with applying the cleaning liquid to the surface of the substrate, at S230. In addition, the method may include drying the surface of the substrate, at S240.

For example, the substrate cleaning method S200 according to some embodiments may be applied to remove a photoresist film or a photoresist pattern formed on the substrate. Impurities remaining on the surface of the substrate may be easily removed through the hydrophilization of the substrate.

Furthermore, the substrate hydrophilized by the substrate processing apparatus according to some embodiments may be applied not only to bonding between substrates and cleaning of substrates, but also to the post-semiconductor processing stage. For example, the plasma treatment of the substrate may be applied to a packaging process of bonding the semiconductor chip to a package substrate. Specifically, electrical reliability and electrical properties between the semiconductor chip and the package substrate may be improved by removing particles or contaminants remaining on the pad on the package substrate, etc. In addition, mechanical reliability may be improved by reducing or preventing peeling of molding compounds provided in the semiconductor packages.

Although the present disclosure has been described above by way of certain embodiments and drawings, aspects are not limited thereto, and it goes without saying that various changes and modifications may be made within the equivalent scope of the technical idea of the present disclosure and the claims to be described below by those of ordinary skill in the art.

1. A substrate processing apparatus, comprising:
a stage configured to support a substrate;
a gas supply device configured to supply a mixed gas including an inert gas and a process gas, wherein the inert gas includes a first inert gas and a second inert gas; and
a reactor configured to receive the mixed gas from the gas supply device and to generate plasma at atmospheric pressure to thereby process a surface of the substrate with the plasma;
wherein the gas supply device includes:
a gas supply unit configured to supply the inert gas;
a flow rate controller configured to control a flow rate of a liquid process gas; and
a vaporizer configured to vaporize the liquid process gas supplied from the flow rate controller.

2. The substrate processing apparatus according to claim 1, further comprising a processing chamber, wherein the reactor and the stage are in the processing chamber, wherein at least a part of the processing chamber is open to maintain atmospheric pressure.

3. The substrate processing apparatus according to claim 1, wherein the gas supply unit includes:
a first gas supply unit configured to supply the first inert gas to the reactor as a plasma generation gas; and
a second gas supply unit configured to supply the second inert gas to the vaporizer as a carrier gas.

4. The substrate processing apparatus according to claim 3, wherein the vaporizer is configured to vaporize all liquid process gas supplied from the flow rate controller and supply vaporized process gas to the reactor through the carrier gas.

5. The substrate processing apparatus according to claim 1, wherein the flow rate controller is configured to control a flow rate of the liquid process gas to any one of 0.01 g/min to 0.08 g/min.

6. The substrate processing apparatus according to claim 5, wherein the flow rate controller is further configured to control the flow rate of the liquid process gas in a unit of 0.01 g/min.

7. The substrate processing apparatus according to claim 1, wherein at least one of the stage or the reactor is configured to move relative to one another along a first direction.

8. The substrate processing apparatus according to claim 7, wherein the reactor is configured to extends along a second direction intersecting the first direction and has a length longer than a length of the substrate in the second direction.

9. The substrate processing apparatus according to claim 8, wherein the stage is configured to move along the first direction at a position spaced apart from the reactor by a predetermined gap in a third direction such that the substrate passes through a plasma region, wherein the third direction is a direction intersecting the first direction and the second direction.

10. The substrate processing apparatus according to claim 8, wherein the reactor is configured to move along the first direction at a position spaced apart from the surface of the substrate by a predetermined gap in a third direction, wherein the third direction is a direction intersecting the first direction and the second direction.

11. The substrate processing apparatus according to claim 1, wherein an RF power supplied to the reactor is configured to be adjusted within a range of 200 W to 500 W.

12. The substrate processing apparatus according to claim 1, wherein the inert gas includes argon (Ar), and the process gas includes water vapor (H₂O).

13. A substrate processing apparatus, comprising:
a stage configured to support a substrate;
a gas supply device configured to supply an inert gas and a process gas;
a reactor configured to receive the inert gas and the process gas from the gas supply device and generate plasma, wherein the inert gas includes a first inert gas and a second inert gas; and
a processing chamber configured to be at least partially open to maintain atmospheric pressure, the reactor and the stage being in the processing chamber, and the processing chamber being configured to process the surface of the substrate at the atmospheric pressure with the plasma,
wherein the gas supply device includes:
a flow rate controller configured to control a flow rate of a liquid process gas;
a vaporizer configured to vaporize a liquid process gas supplied from the flow rate controller and supply vaporized process gas to the reactor;
a first gas supply unit configured to supply the first inert gas to the reactor as a plasma generation gas; and
a second gas supply unit configured to supply the second inert gas to the vaporizer as a carrier gas.

14. The substrate processing apparatus according to claim 13, wherein the flow rate controller is configured to control the flow rate of the liquid process gas to any one of 0.01 g/min to 0.08 g/min.

15. The substrate processing apparatus according to claim 13, wherein
the inert gas includes argon (Ar),
a flow rate of the plasma generation gas supplied by the first gas supply unit is 15 Lpm to 20 Lpm, and
a flow rate of the carrier gas supplied by the second gas supply unit is constant.

16. The substrate processing apparatus according to claim 13, wherein the vaporizer is configured to vaporize all liquid process gas supplied from the flow rate controller and supply vaporized process gas to the reactor at a constant concentration through the carrier gas.

17. The substrate processing apparatus according to claim 13, wherein
the reactor includes a linear opening for generating linear plasma, and
the stage is further configured to move such that the substrate passes through the linear plasma.

18. The substrate processing apparatus according to claim 13, wherein the flow rate controller includes:
a storage unit configured to store the liquid process gas; and
a flow regulator connected to the storage unit and configured to control the flow rate of the liquid process gas and supply the liquid process gas to the vaporizer.

19. A substrate processing apparatus, comprising:
a stage configured to support a substrate;
a gas supply device configured to supply a mixed gas including an argon (Ar) gas and a water vapor (H₂O);
a linear reactor configured to receive the mixed gas from the gas supply device and generate linear plasma, wherein a surface of the substrate is processed by plasma generated in the linear reactor and is spaced apart from the linear reactor by a predetermined gap such that the substrate passes through the plasma; and
a processing chamber configured to be at least partially open to maintain atmospheric pressure, the linear reactor and the stage being in the processing chamber, and the processing chamber is configured to process the surface of the substrate at the atmospheric pressure,
wherein the gas supply device includes:
a flow rate controller including a storage unit configured to store liquid process gas, and a flow regulator connected to the storage unit to control a flow rate of the liquid process gas within a range of 0.01 g/min to 0.08 g/min;
a vaporizer configured to vaporize liquid process gas supplied from the flow rate controller and supply vaporized process gas to the linear reactor at a constant concentration;
a first gas supply unit configured to supply the argon gas to the linear reactor such that the linear reactor generates the plasma; and
a second gas supply unit configured to supply the argon gas to the vaporizer as a carrier gas.

20. The substrate processing apparatus of claim 19, wherein at least one of the stage or the reactor is configured to move relative to one another along a first direction.
